(19) United States
(12) Patent Application Publication
(10) Pub. No.: US 2025/0038008 A1
(43) Pub. Date: Jan. 30, 2025

(54) METHODS FOR CHEMICAL MECHANICAL POLISHING AND METHODS FOR FORMING AN INTERCONNECT STRUCTURE OF A SEMICONDUCTOR DEVICE

(71) Applicant: Taiwan Semiconductor Manufacturing Company, Ltd., Hsinchu (TW)

(72) Inventors: Ming-Hsiang Cheng, Hsinchu (TW); Ting-Kui Chang, New Taipei (TW); Fu-Ming Huang, Changhua (TW); Li-Chieh Wu, Hsinchu (TW); Che-Hao Tu, Hsinchu (TW)

(73) Assignee: Taiwan Semiconductor Manufacturing Company, Ltd., Hsinchu (TW)

(21) Appl. No.: 18/360,930

(22) Filed: Jul. 28, 2023

(51) Int. Cl. H01L 21/321; C09G 1/02; H01L 21/768

(52) U.S. Cl. CPC H01L 21/3212; C09G 1/02; H01L 21/7684

(57) ABSTRACT

Methods for chemical mechanical polishing (CMP), and methods for forming an interconnect structure of a semiconductor device are provided. The methods include performing CMP on a surface of a dielectric structure with a CMP slurry to remove a portion of a metal layer formed in the dielectric structure and having at least a first layer exposed through the surface. In some examples, the CMP slurry that includes an abrasive, an oxidizing agent, and a compound configured to reduce aggregation of the abrasive on the surface of the dielectric structure. In some examples, the compound has positively charged ions that interact with the abrasive to reduce aggregation of the abrasive on a dielectric material. In some examples, the CMP slurry includes potassium hydroxide. In some examples, the compound includes an ammonium salt.

### BACKGROUND

The semiconductor integrated circuit (IC) industry has continued its rapid growth in recent years. Technological advancements in IC materials and design have led to continuous improvements in the generations of ICs. With each new generation, the circuits become smaller and more complex than their predecessors, resulting in higher functional density (i.e., the number of interconnected devices per chip area) and smaller geometric sizes (i.e., the smallest component or line that can be created using a fabrication process). This scaling down process has been beneficial in increasing production efficiency and reducing associated costs. However, as feature sizes continue to shrink, the manufacturing process becomes more challenging, and it becomes increasingly difficult to ensure the reliability of semiconductor devices. As a result, the industry faces the ongoing challenge of developing processes that can create smaller, more reliable ICs.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 schematically represents a cross-sectional view of a portion of a semiconductor device at one stage in an integrated circuit manufacturing process in accordance with some embodiments.

FIG. 2 is a flowchart illustrating an exemplary method for forming a semiconductor structure in accordance with some embodiments.

FIGS. 3A-3C schematically represent a method of forming an interconnect structure in accordance with some embodiments.

FIGS. 4A-4C schematically represent cross-sectional views of samples subsequent to CMP performed during experimental investigations leading to certain aspects of an embodiment.

FIG. 5 schematically represents a cross-sectional view of a sample subsequent to CMP performed during experimental investigations leading to certain aspects of an embodiment.

FIG. 6 is a graph representing optical measurements of samples subsequent to CMP performed during experimental investigations leading to certain aspects of an embodiment.

FIG. 7 represents three magnifications of a sample IC and FIG. 8 represents atomic force measurements obtained from a first hot spot of the sample IC after completion of CMP performed during experimental investigations leading to certain aspects of an embodiment.

FIG. 9 represents three magnifications of a sample IC and FIG. 10 represents atomic force measurements obtained from a second hot spot of the sample IC after completion of CMP performed during experimental investigations leading to certain aspects of an embodiment.

FIG. 11 schematically represents interaction between components of a CMP slurry and a dielectric structure in accordance with some embodiments.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

For the sake of brevity, certain techniques related to semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present. When an element or layer is referred to as being “on” another element or layer, it is directly on and in contact with the other element or layer.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

Some embodiments of the disclosure will now be described with reference to the drawings, wherein like reference numerals are generally used to refer to like elements throughout. In the following description, for purposes of explanation, numerous specific details are set forth in order to provide a thorough understanding of the claimed subject matter. It is evident, however, that the claimed subject matter may be practiced without these specific details. In other instances, structures and devices are illustrated in block diagram form in order to facilitate describing the claimed subject matter.

Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

As used herein, a “layer” is a region, such as an area comprising arbitrary boundaries, and does not necessarily comprise a uniform thickness. For example, a layer can be a region comprising at least some variation in thickness.

Chemical mechanical polishing (CMP) is widely used in the fabrication of ICs. As an IC is built layer-by-layer on a surface of a semiconductor wafer, CMP is used to planarize the topmost layer or layers to provide a level surface for subsequent fabrication operations. CMP is carried out by placing the semiconductor wafer in a wafer carrier that presses the wafer surface to be polished against a polishing pad attached to a platen. The platen and the wafer carrier are counter-rotated while a CMP slurry containing both abrasive particles and reactive chemicals is applied to the polishing pad. The CMP slurry is transported to the wafer surface via the rotation of the polishing pad. The relative movement of the polishing pad and the wafer surface coupled with the reactive chemicals in the CMP slurry allows CMP to level the wafer surface by means of both physical and chemical actions. CMP can be used at a number of points during the fabrication of an integrated circuit.

However, severe oxide dishing may occur during CMP. Semiconductors include various materials with different properties and therefore pattern geometry can significantly affect planarization. For example, a nonuniform area fraction and layout of the pattern may result in nonuniform pressure distribution during CMP. Consequently, the pattern may be slightly over polished to remove harder materials which can result in excessive thinning (i.e., dishing) of softer materials. Although this can affect various materials at different stages of the manufacturing process, the examples discussed herein will focus on oxide dishing, particularly an excessive removal of a dielectric material during formation of an interconnect structure. Oxide dishing may be caused by, for example, prolonged polish times, high oxide-to-copper removal rate ratios, and local hydrophobicity on different materials.

Presented herein are embodiments of semiconductor structures and of methods for forming semiconductor structures with reduced oxide dishing during CMP and with CMP slurries that are configured to reduce oxide dishing during planarization. For convenience, the methods will be described herein in reference to planarization during formation of interconnect structures. However, the methods are not limited to this application and/or stage of the IC production process.

In various embodiments, the CMP slurries include an abrasive and at least one compound configured to reduce aggregation of the abrasive on the surface of the dielectric structure, and thereby reduce dishing of the dielectric structure. In some embodiments, the compound has positively charged ions that interact with the negatively charged particles of the abrasive to cause the reduction in aggregation of the abrasive on the dielectric material.

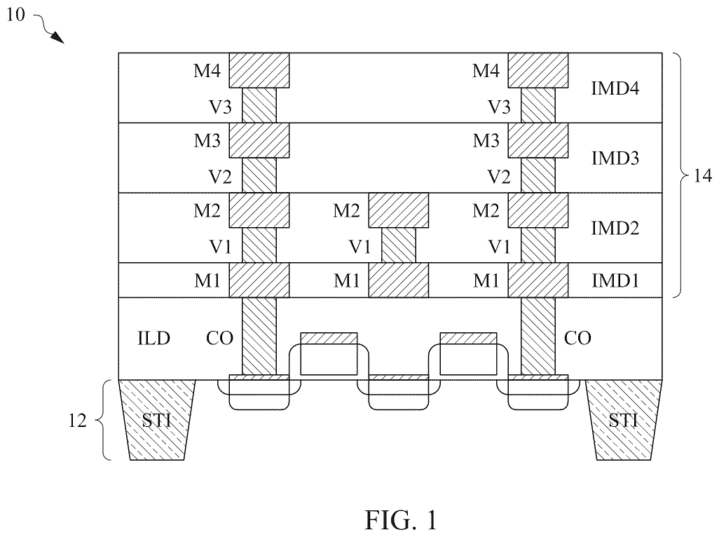

FIG. 1 is a cross-sectional view of a portion of an example semiconductor device 10 at one stage in an integrated circuit manufacturing process in accordance with an embodiment. Shown is a portion of the semiconductor device 10 having electrical circuitry formed in and/or upon a substrate 12. The substrate 12 may be one of a variety of types of semiconductor substrates commonly employed in semiconductor integrated circuit fabrication, and integrated circuits may be formed therein and/or thereupon. The semiconductor substrate may be of any construction comprising semiconductor materials, including but not limited to, bulk silicon, a semiconductor wafer, a silicon-on-insulator (SOI) substrate, or a silicon germanium substrate. Other semiconductor materials, including group III, group IV, and/or group V semiconductors, can be used.

In some embodiments, the substrate 12 can include a plurality of functional regions. The plurality of functional regions can be defined and electrically isolated from each other by isolation features, such as shallow trench isolations (STI) features or local oxidation of silicon (LOCOS) features, but the disclosure is not limited thereto. Various electrical components may be formed over the substrate 12. Examples of the electrical components include active devices, such as transistors and diodes, and passive devices, such as capacitors, inductors, and resistors. As shown in FIG. 1, in some embodiments, active devices, i.e., transistors, can be formed over the substrate 12. The functional regions isolated by the isolation features may include microelectronic elements formed in and/or upon the substrate 12. Examples of the types of microelectronic elements that may be formed in the substrate 12 include, but are not limited to, transistors such as metal oxide semiconductor field effect transistors (MOSFETs), complementary metal oxide semiconductor (CMOS) transistors, bipolar junction transistors (BJTs), high voltage transistors, high frequency transistors, p-channel and/or n-channel field effect transistors (PFETs/NFETs), resistors, diodes, capacitors, inductors, fuses, and/or other suitable elements. Various processes are performed to form the various microelectronic elements, including but not limited to one or more of deposition, etching, implantation, photolithography, annealing, and other suitable processes. The microelectronic elements are interconnected to form the integrated circuit device, which may comprise one or more of a logic device, memory device (e.g., SRAM), radio frequency (RF) device, input/output (I/O) device, system-on-chip (SoC) device, and other suitable types of devices.

An inter-layer dielectric layer ILD can be formed over the various electrical components, and contact plugs CO may be formed in the inter-layer dielectric layer ILD for providing electrical connections between other circuitry/elements. The formation operations of the contact plugs CO can include forming openings in the inter-layer dielectric layer ILD, filling the openings with conductive materials, and performing a planarization such as CMP. In some embodiments, the contact plugs CO can include tungsten (W), but other suitable conductive material such as silver (Ag), aluminum (Al), copper (Cu), AlCu, or the like may also be used.

A BEOL (back end of line) interconnect structure 14 can be formed over the inter-layer dielectric layer ILD and the contact plugs CO. In some embodiments, the BEOL interconnect structure 14 includes a plurality of conductive layers. For example, the BEOL interconnect structure 14 includes a plurality of metal layers labeled M1 through M4 and a plurality of conductors labeled V1 through V3. Further, the metal layers M1 through M4 and the conductors V1 through V3 are disposed in a plurality of inter-metal dielectric layers labeled IMD1 through IMD4. The inter-metal dielectric layers IMD1 through IMD4 may provide electrical insulation as well as structural support for the various features during many fabrication operations.

The inter-metal dielectric layers IMD1 through IMB4 may include one or more of low-k dielectric materials, fluorine-doped silicon dioxide, organosilicates, carbon-doped oxides, porous silicon dioxide, organic polymeric dielectrics (e.g., polyimide, polynorbornenes, benzocyclobutene, and PTFE), silicon based polymeric dielectrics (e.g., hydrogen silsesquioxane, methylsilsesquioxane), and other commonly used materials. The dielectric constants (k value) of the low-k dielectric materials can be less than about 3.9, less than about 3.5, or less than about 2.8.

In some embodiments, the metal layers M1 through M4 and the conductors V1 through V3 may each include a single layer or two or more layers. In some embodiments, metal layers M1 through M4 and the conductors V1 through V3 may each include a fill material and a liner between the fill material and the dielectric material of the corresponding inter-metal dielectric layers IMD1 through IMD4. In some embodiments, the layers may include a liner formed of a noble metal or alloy thereof such as, but not limited to, rhenium (Re), rhodium (Rh), ruthenium (Ru), or alloys thereof. In some embodiments, the layers may include a fill material formed of copper (Cu), aluminum (Al), tungsten (W), silver (Ag), or alloys thereof.

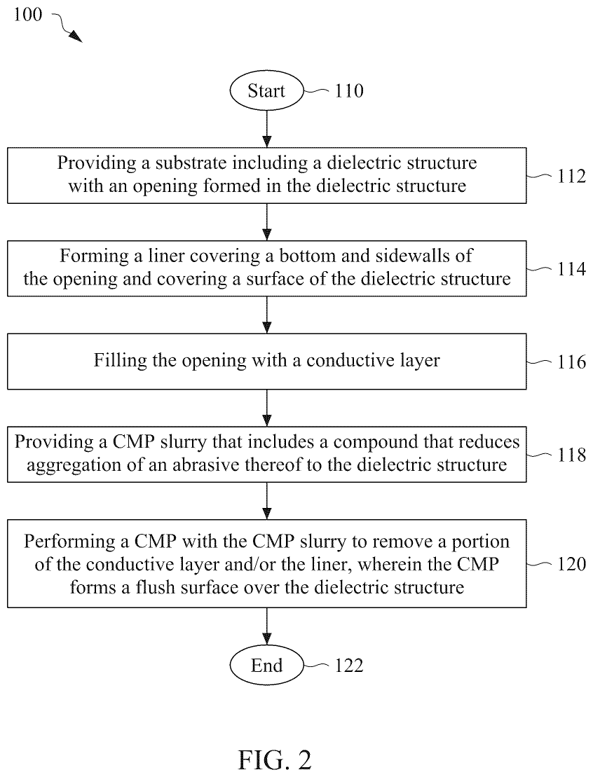

Referring to FIG. 2, an exemplary method 100 is presented for forming a semiconductor structure. In some embodiments, the method 100 may be used to form an interconnect structure such as the BEOL interconnect structure 10 of FIG. 1. The method 100 may start at 110. At 112, the method 100 includes providing a substrate (e.g., the substrate 12) including a dielectric structure disposed thereon with openings formed therein. In some embodiments, the openings may include a trench and/or a via formed in the dielectric structure. In some embodiments, the dielectric structure may include a single layer. In some alternative embodiments, the dielectric structure may include a multi-layered structure including a plurality of dielectric layers.

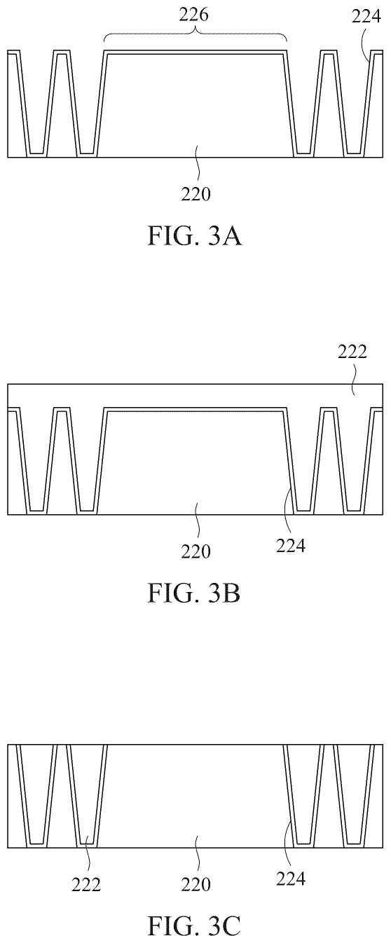

At 114, the method 100 includes forming a liner covering a bottom and sidewalls of the opening in the dielectric structure. In some embodiments, the liner may additionally cover a surface of the dielectric structure. For example, FIG. 3A schematically represents a dielectric structure 220 having openings therein and a liner 224 formed over surfaces of the dielectric structure 220 covering the bottoms and sidewalls of the openings. In some embodiments, the liner 224 may include a noble metal or alloy thereof such as, but not limited to, rhenium (Re), rhodium (Rh), ruthenium (Ru), or alloys thereof. The dielectric structure 220 includes a relatively large region or gap 2265 between the openings, for example, greater than about 0.2 micrometers.

At 116, the method 100 includes filling the openings with a conductive layer (i.e., fill material). For example, FIG. 3B schematically represents a conductive layer 222 that fills the openings and covers the liner 224. In some embodiments, the conductive layer 222 may include a metal or alloy of high electric conductivity. As nonlimiting examples, the conductive layer 222 may include copper (Cu), aluminum (Al), tungsten (W), silver (Ag), or alloys thereof. In some embodiments, a thickness of the conductive layer 222 is greater than a thickness of the liner 224.

At 118, the method 100 includes providing a CMP slurry. In some embodiments, the CMP slurry includes a carrier fluid comprising at least one abrasive configured to function as a polishing agent. In some embodiments, the abrasive includes a particulate having, for example, submicron-sized particles. In various embodiments, the abrasive may be a metal oxide. In various embodiments, the abrasive is a metal oxide selected from the group including alumina, titania, zirconia, germania, silica, ceria, and mixtures thereof. For example, the abrasive may include silica (e.g., silicon dioxide (SiO₂)) which typically provides a relatively high polish rate for dielectric materials. As another example, the abrasive may include titanium dioxide (TiO₂) which typically provides a relatively high polish rate for ruthenium oxide (RuO₂).

The size and shape of the abrasive particles can be tailored to achieve specific polishing characteristics. In various embodiments, the abrasive may include a particulate comprising one or more materials having particle sizes of between about 10 nm and about 300 nm, such as about 100 nm to about 200 nm, such as about 150 nm. In various embodiments, the CMP slurry may include about 1.0 to about 15.0 weight percent or more of the abrasive, such as about 2.0 to about 6.0 wt. %. The abrasive may be produced by any technique known to those skilled in the art. For example, metal oxide abrasives can be produced using various high temperature process such as sol-gel, hydrothermal, or plasma processes, or by processes for manufacturing fumed or precipitated metal oxides.

In some embodiments, the CMP slurry includes at least one oxidizing agent configured to promote metal dissolution during chemical mechanical processes. In various embodiments, the oxidizing agent may include a composition that will chemically react with one of more layers of metal layers (e.g., M1 through M4) and/or one or more layers of conductors (e.g., V1 through V3) in order to assist with removal of portions thereof. In some embodiments, the oxidizing agent may include at least one composition that has an electrochemical potential greater than the electrochemical potential necessary to oxidize the first metal layer and/or the second metal layer.

In some embodiments, the oxidizing agent promotes dissolution of copper and alloys thereof, aluminum and alloys thereof, and/or combinations thereof. In various embodiments, the oxidizing agent promotes dissolution of a noble metal, such as ruthenium (Ru). In various embodiments, the oxidizing agent includes hydrogen peroxide (H₂O₂), potassium permanganate (KMnO₄), ferric nitrate (Fe(NO₃)₃), or sodium periodate (NalO₄). In various embodiments, the CMP slurry may include about 0.3 to about 17.0 wt. % of the oxidizing agent, such as about 1.0 to about 12.0 wt. %.

In some embodiments, the CMP slurry includes at least one compound configured to reduce aggregation of the abrasive on a surface of a dielectric material (e.g., the dielectric structure). In some embodiments, the compound has positively charged ions that interact with the abrasive to reduce aggregation of particles of the abrasive on the dielectric material. In some embodiments, the compound includes an ammonium salt (e.g., primary (one degree), secondary (two degrees), tertiary (three degrees), or quaternary (four degrees)), such as a quaternary ammonium salt, such as an organic base tetraethylammonium hydroxide (TEAH; (C₂H₅)₄NOH). In some embodiments, the compound is a component of a pH adjustor. In various embodiments, the CMP slurry may include about 0.1 to about 10.0 wt. % of the compound, such as about 0.5 to about 5.0 wt. %.

In some embodiments, the CMP slurry includes one or more additional components such as, but not limited to, various chelating agents, surfactants, stabilizers, corrosion inhibitors, pH adjustors, and other additives. Chelating agents may be compounds that are configured to bind to metal ions and thereby reduce the likelihood of the metal ions reacting with other components of the CMP slurry. Surfactants may be compounds that are configured to reduce the surface tension between two liquids or a liquid and a solid and thereby promote uniform dispersion of solid particles (e.g., the abrasive) in the carrier fluid. Stabilizers may be compounds that are configured to reduce agglomeration of solid particles (e.g., the abrasive) in the carrier fluid and to maintain a stable pH and viscosity during polishing. Corrosion inhibitors may be compounds that are configured to reduce the likelihood of corrosion of one or more metals, such as the first metal layer and/or the second metal layer. pH adjustors may be compounds that are configured to modify the pH of the CMP slurry.

The carrier fluid may be a solvent that is configured to function to carry the various compounds of the CMP slurry and allow the mixture to be moved and dispersed onto a polishing pad. In some embodiments the solvent may be deionized water or an alcohol. However, any other suitable solvents may also be utilized. The specific solvent may be determined based on a predetermined polishing rate and selectivity. In some embodiments, the concentration of the carrier fluid in the CMP slurry may be between about 99% by volume and about 70% by volume, such as about 95% by volume.

Any compounds that are known in the art to be useful in chemical mechanical polishing slurries and compositions may be incorporated into the slurry of the present disclosure. The exact composition and concentration of each component can vary depending on the specific application and desired polishing performance.

At 120, the method 100 includes performing CMP with the CMP slurry to remove a portion of the conductive layer and/or the liner and form a flush surface over the dielectric structure. As used herein, a flush surface refers to a surface having a topography with a height variation of less than 4 nm, and in some embodiments less than 3 nm, and in some embodiments less than 2.5 nm. In some embodiments, more than one CMP may be performed with the CMP slurry. In some embodiments, one or more CMP and/or etching processes may be performed with a composition different than the CMP slurry prior to or subsequent performing the CMP with the CMP slurry. FIG. 3C schematically represents the interconnect structure subsequent to performing the CMP with the CMP slurry. Notably, the interconnect structure has a flush surface over the dielectric structure 220. The method 100 may end at 122.

In some embodiments, the dielectric structure and the metal layers (e.g., the liner and the conductive layer) are all exposed to the surrounding environment at a surface of the dielectric structure. In some embodiments, a ratio of the exposed surface area of the metal layers to the dielectric structure (i.e., pattern density) is less than approximately 65%, such as less than approximately 50%, such as less than approximately 40%, such as less than approximately 30%, such as less than approximately 20%, such as less than approximately 5%.

As mentioned above, severe oxide dishing may occur during CMP. According to the method 100, the CMP slurry includes a compound (e.g., TEAH) configured to reduce aggregation of the abrasive on the dielectric structure. The inclusion of the compound may decrease the oxide removal rate, and provide steric hindrance with the abrasive which may improve post-polishing topography of the dielectric structure. Accordingly, severe oxide dishing may be reduced or avoided and a metal layer having a surface flush with the surface of the dielectric structure may be obtained.

While not intending to be limited to any particular theory, the aggregation of the abrasive on the dielectric structure may be at least partially due to an interaction between the dielectric structure, the abrasive, and positively charged ions in the slurry (e.g., potassium ions (K+) from potassium hydroxide). Inclusion of the compound configured to reduce aggregation of the abrasive (e.g., TEAH) may disrupt this phenomenon by introducing additional positively charged ions (e.g., tetraethylammonium ions (TEA+)) which compete with the positively charged ions (e.g., potassium ions) for interaction with the abrasive. Particles of the abrasive that interact with the additional positively charged ions (e.g., tetraethylammonium ions) have a reduced attraction to the dielectric structure as the additional positively charged ions increase repulsion between the abrasive and the dielectric structure.

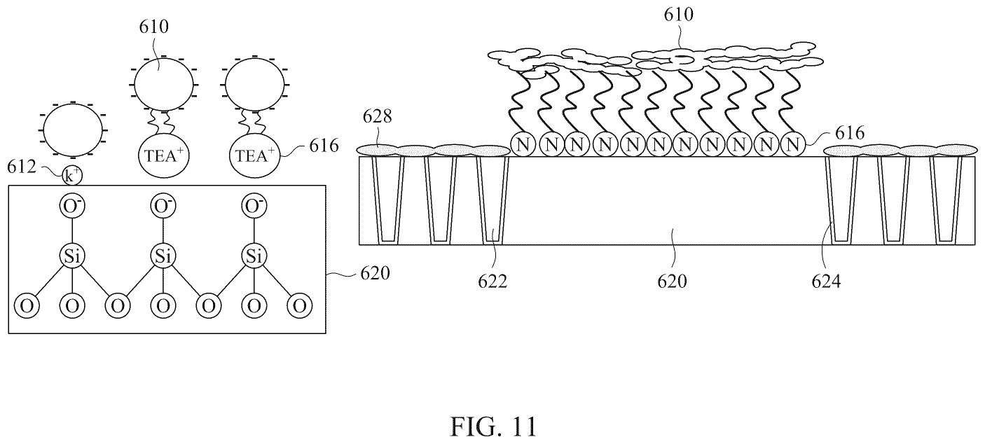

For example, FIG. 11 schematically represents the CMP slurry applied to a dielectric structure 620 that includes metal layers having a conductive layer (i.e., fill material) 622 and a liner 624 between the conductive layer 622 and the dielectric structure 620. FIG. 11 includes an atomic scale illustration (left) and a cross-sectional view (right). Components of the CMP slurry represented include abrasive particles 610, positively charged potassium ions (612; K⁺) from potassium hydroxide (e.g., a pH adjustor), positively charged tetraethylammonium ions (616; TEA⁺), particles of a corrosion inhibitor 628 (e.g., copper corrosion inhibitor), and oxygen (O⁻) and silicon (Si) molecules of the dielectric structure 620. As represented, the TEA+ ions 616 interact with the abrasive particles 610 and thereby reduces the aggregation of the abrasive particles 610 on the surface of the dielectric structure 620.

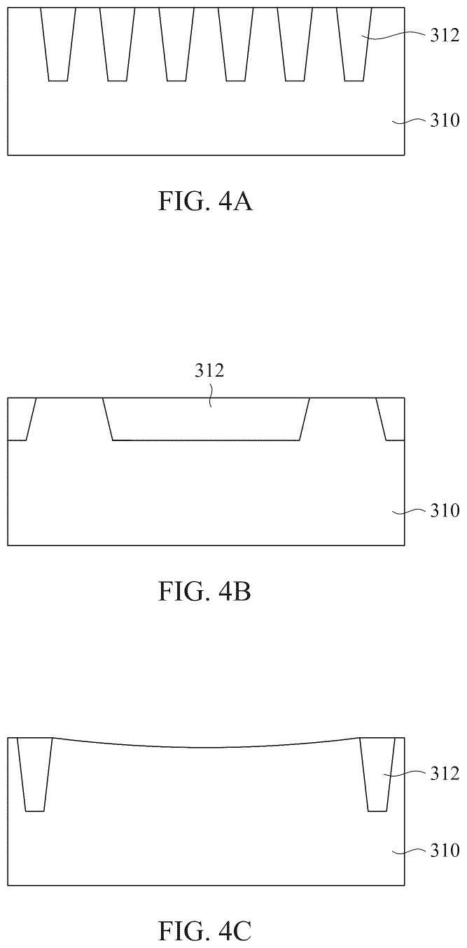

FIGS. 4A-10 present results of various experimental investigations leading to aspects of some of the embodiments disclosed herein.

FIGS. 4A-4C schematically represent cross-sectional views of samples that each included low-K dielectric structures with metal layers therein that each included a first layer (e.g., a fill material) of copper and a second layer (i.e., a liner) of ruthenium. The figures represent the topography of the samples after completion of CMP using the CMP slurry (with TEAH). The samples varied from a dense pattern defined by having a minimum pitch of less than 30 nm (e.g., a pitch of about 25 nanometers; FIG. 4A), to a wide metal pattern (e.g., metal layers with widths of greater than 100 nm and a pattern density of greater than 60%; FIG. 4B), to an iso pattern (e.g., metal layers with widths of less than about 20 nm and a pattern density of less than 20%; FIG. 4C).

The dense pattern sample had a height of the metal layers 312 of about 19-21 nm and an oxide dishing of about 0 nm, the wide metal pattern sample had a height of the metal layers 312 of about 16-18 nm and an oxide dishing of about 0 nm, and the iso pattern sample had a height of the metal layers 312 of about 21-23 nm and an oxide dishing of about 3 nm. If CMP had been performed with a comparable slurry that did not include the TEAH, it would be expected that the dense pattern sample would have a height of the metal layers of about 19-21 nm and an oxide dishing of about 0 nm, the wide metal pattern sample would have a height of the metal layers of about 12-14 nm and an oxide dishing of about 0 nm, and the iso pattern sample would have a height of the metal layers of about 15-17 nm and an oxide dishing of about 10 nm. As such, relative to results that may be expected to otherwise occur, the CMP slurry provided similar results for the dense pattern samples, improved height of the metal layers (about 4 nm) for the wide metal pattern samples, and improved height of the metal layers (about 6 nm) and reduced oxide dishing (about 7 nm) for the iso pattern samples.

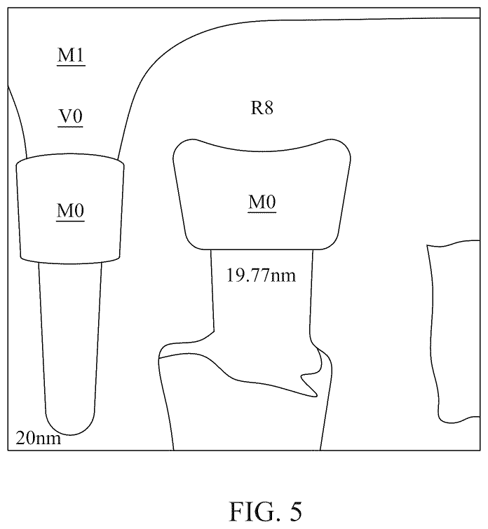

FIG. 5 schematically represents an isolated view of a sample having a conductor (i.e., an interconnect structure) V0 connecting metal layers M0 and M1 after performance of CMP using the CMP slurry. Parameters of the CMP were adjusted to provide a target height for M0 of 20 nm. Subsequent the CMP, M0 had a height of about 19-21 nm and V0 was good quality. These results were improvements over samples that underwent CMP with other slurries that did not include TEAH in which M0 had a height of about 13-14 nm and V0 was relatively poor quality.

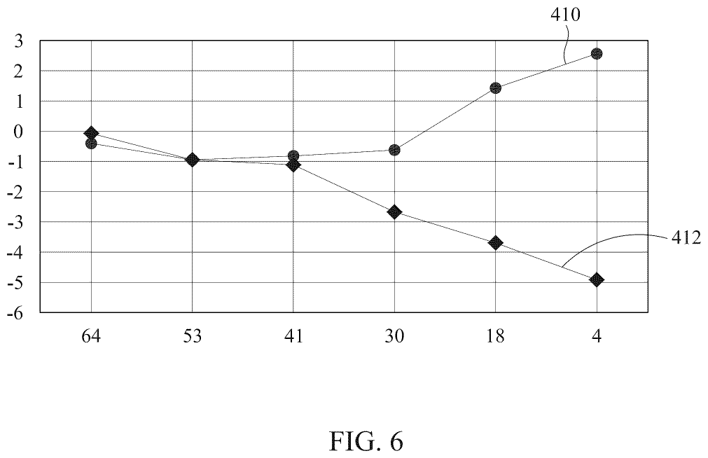

FIG. 6 is a graph representing optical measurements of samples subsequent to CMPs. The graph represents a topography of M0 (y-axis; nanometers) relative to pattern density (x-axis; percent). For all samples, the widths of M0 were 18 nm. The length of the dielectric material between adjacent metal layers were 10 nm, 16 nm, 26 nm, 42 nm, 82 nm, and 482 nm. A first set 410 of the samples underwent CMP using the CMP slurry, and a second set 412 of the samples underwent CMP using a different slurry that did not include the TEAH. The results indicated that the CMP slurry achieved a higher topography of between about 0 and +2.5 nm whereas the other slurry achieved a lower topography of between about 0 and −5 nm.

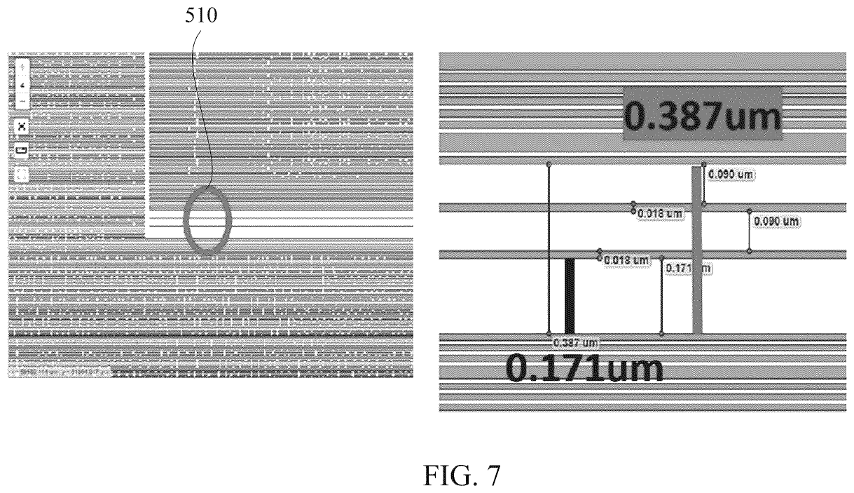

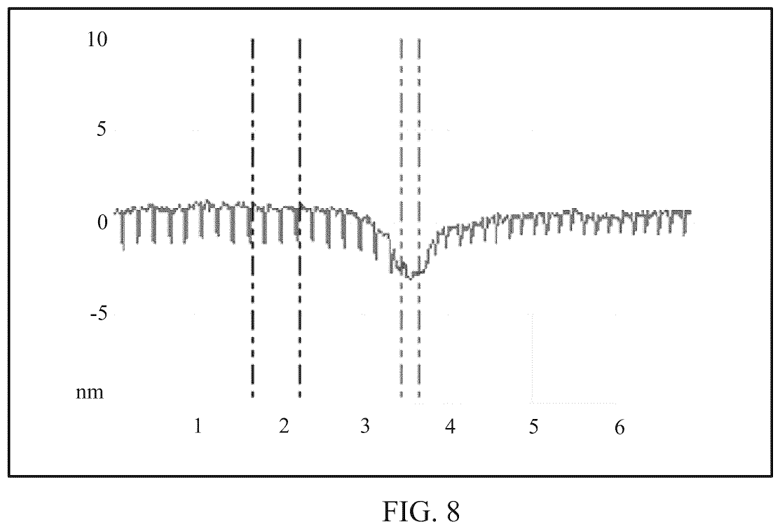

FIG. 7 represents two magnifications of a sample IC and FIG. 8 represents atomic force measurements obtained from a first hot spot 510 of the sample IC after completion of CMP using the CMP slurry. The first hot spot 510 had a region or gap of the dielectric material between adjacent metal layers with a dimension of about 0.387 micrometers. The sample IC showed a topography decrease (i.e., dishing) at the hot spot 510 of about 3.5 nm (about 5.8 nm improvement over samples planarized with other slurries).

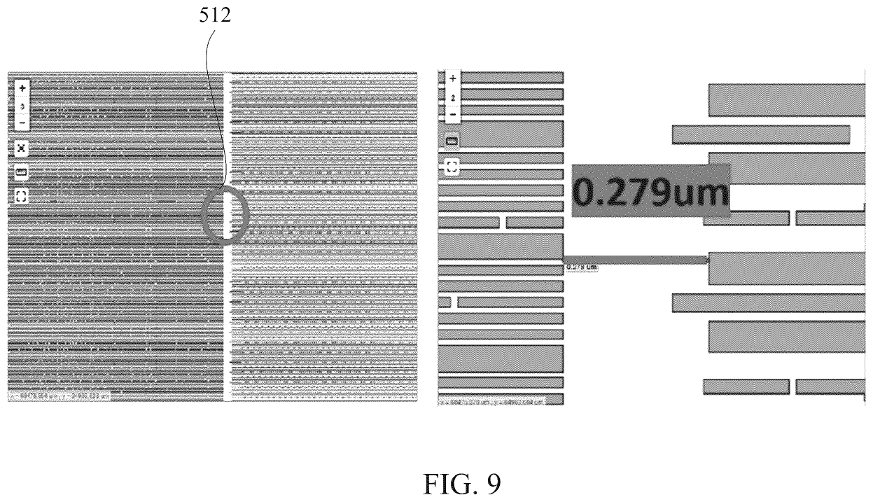

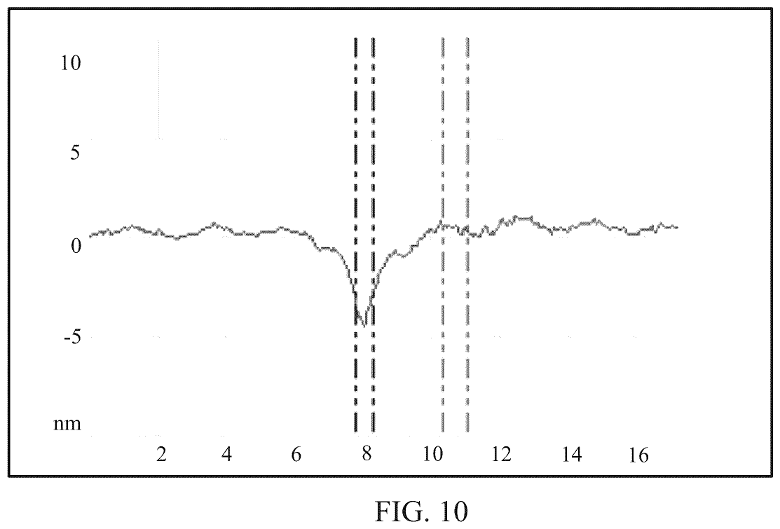

FIG. 9 represents two magnifications of a sample IC and FIG. 10 represents atomic force measurements obtained from a second hot spot 512 of the sample IC after completion of CMP using the CMP slurry. The second hot spot 512 had a region or gap of the dielectric material between adjacent metal layers having a dimension of about 0.279 micrometers. The sample IC showed a topography decrease (i.e., dishing) of about 4.2 nm (about a 6.6 nm improvement over samples planarized with other slurries).

The present disclosure therefore provides methods for forming a semiconductor structure with CMP and CMP slurries that may significantly reduce oxide dishing, especially for workpieces having relatively low pattern densities, such as below 40%, such as below 30%. In some embodiments, the CMP slurries include a compound configured to reduce aggregation of an abrasive on a dielectric material. In some embodiments, the compound is TEAH.

In accordance with an embodiment, a method is provided for CMP. The method includes providing a CMP slurry that includes an abrasive, an oxidizing agent configured to promote dissolution of a metallic material, and an ammonium salt having positively charged ions that interact with the abrasive to reduce aggregation of the abrasive on a dielectric material, and performing CMP on a surface of a dielectric structure with the CMP slurry to remove a portion of a metal layer formed in the dielectric structure and having at least a first layer exposed through the surface.

In accordance with another embodiment, a method is provided for CMP. The method includes receiving a dielectric structure comprising a metal layer formed therein, wherein the metal layer includes at least a first layer exposed through a surface of the dielectric structure, providing a CMP slurry that includes at least an abrasive and a pH adjustor that includes potassium hydroxide and a compound configured to reduce aggregation of the abrasive on the surface of the dielectric structure, and performing CMP on the surface with the CMP slurry to remove a portion of the metal layer.

In accordance with yet another embodiment, a method is provided for forming an interconnect structure of a semiconductor device. The method includes receiving a substrate comprising a dielectric structure and a metal layer formed in the dielectric structure, wherein the metal layer includes at least a first layer and a second layer, wherein the second layer is between and separates the dielectric structure and the first layer, wherein the first layer includes copper or an alloy thereof, wherein the second layer includes a noble metal or alloy thereof, wherein at least the first layer and the metal layer are exposed through a surface of the dielectric structure, wherein the dielectric structure includes a dielectric material that has a relative dielectric constant (κ) of less than 3.9, providing a CMP slurry that includes at least an abrasive and a compound configured to reduce aggregation of the abrasive on the surface of the dielectric structure, and performing chemical mechanical polishing (CMP) on the surface with the CMP slurry to remove a portion of the metal layer to form the interconnect structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A method for chemical mechanical polishing (CMP), comprising:
providing a CMP slurry that includes an abrasive, an oxidizing agent configured to promote dissolution of a metallic material, and an ammonium salt having positively charged ions that interact with the abrasive to reduce aggregation of the abrasive on a dielectric material; and
performing CMP on a surface of a dielectric structure with the CMP slurry to remove a portion of a metal layer formed in the dielectric structure and having at least a first layer exposed through the surface.

2. The method of claim 1, wherein the CMP slurry includes potassium hydroxide.

3. The method of claim 1, wherein the ammonium salt is tetraethylammonium hydroxide (TEAH).

4. The method of claim 1, wherein the metallic material is copper or an alloy thereof.

5. The method of claim 1, wherein the dielectric material has a relative dielectric constant (κ) of less than 3.9.

6. The method of claim 1, wherein the metallic material is a noble metal or an alloy thereof.

7. The method of claim 1, wherein the CMP slurry includes about 0.1 wt. % to about 10.0 wt. % of the ammonium salt.

8. A method for chemical mechanical polishing (CMP), comprising:
receiving a dielectric structure comprising a metal layer formed therein, wherein the metal layer includes at least a first layer exposed through a surface of the dielectric structure;
providing a CMP slurry that includes at least an abrasive and a pH adjustor that includes potassium hydroxide and a compound configured to reduce aggregation of the abrasive on the surface of the dielectric structure; and
performing CMP on the surface with the CMP slurry to remove a portion of the metal layer.

9. The method of claim 8, wherein the compound includes positively charged ions that interact with the abrasive to cause a reduction in aggregation of the abrasive on the dielectric structure.

10. The method of claim 8, wherein the compound is tetraethylammonium hydroxide (TEAH).

11. The method of claim 8, wherein the first layer is copper or an alloy thereof, and the metal layer includes a second layer between the dielectric structure and the first layer, wherein the second layer is a noble metal or an alloy thereof, and wherein the dielectric structure includes a dielectric material that has a relative dielectric constant (κ) of less than 3.9.

12. The method of claim 11, wherein performing the CMP on the surface is performed with a target height of the metal layer of 20 nm, and:
wherein the surface has a dense pattern with a pitch of less than 30 nm, and performing the CMP on the surface results in a height of the metal layer of between 19 and 21 nm;
wherein the surface has a wide metal pattern with a metal layer to dielectric structure pattern density of greater than 60 percent, the metal layer has a width at the surface of greater than 100 nm, and performing the CMP on the surface results in a height of the metal layer of between 16 and 18 nm; or
wherein the surface has an iso pattern with a metal layer to dielectric structure pattern density of less than 20 percent, the metal layer has a width at the surface of less than 20 nm, and performing the CMP on the surface results in a height of the metal layer of between 20 and 23 nm.

13. The method of claim 11, wherein the metal layer is a first metal layer spaced apart on the dielectric structure from a second metal layer at the surface by a dimension of greater than 300 nm, wherein performing the CMP on the surface results in a dishing of the dielectric structure between the first metal layer and the second metal layer of 4 nm or less.

14. The method of claim 8, wherein the CMP slurry includes about 1.0 wt. % to about 10.0 wt. % of the compound.

15. A method for forming an interconnect structure of a semiconductor device, comprising:
receiving a substrate comprising a dielectric structure and a metal layer formed in the dielectric structure, wherein the metal layer includes at least a first layer and a second layer, wherein the second layer is between and separates the dielectric structure and the first layer, wherein the first layer includes copper or an alloy thereof, wherein the second layer includes a noble metal or alloy thereof, wherein at least the first layer and the second layer are exposed through a surface of the dielectric structure, wherein the dielectric structure includes a dielectric material that has a relative dielectric constant (κ) of less than 3.9;
providing a CMP slurry that includes at least an abrasive and a compound configured to reduce aggregation of the abrasive on the surface of the dielectric structure; and
performing chemical mechanical polishing (CMP) on the surface with the CMP slurry to remove a portion of the metal layer to form the interconnect structure.

16. The method of claim 15, wherein the compound includes positively charged ions that interact with the abrasive to cause a reduction in aggregation of the abrasive on the dielectric structure.

17. The method of claim 15, wherein the compound is tetraethylammonium hydroxide (TEAH).

18. The method of claim 15, wherein performing the CMP on the surface is performed with a target height of the metal layer of 20 nm, and:
wherein the surface has a dense pattern with a pitch of less than 30 nm, and performing the CMP on the surface results in a height of the metal layer of between 19 and 21 nm;
wherein the surface has a wide metal pattern with a metal layer to dielectric structure pattern density of greater than 60 percent, the metal layer has a width at the surface of greater than 100 nm, and performing the CMP on the surface results in a height of the metal layer of between 16 and 18 nm; or
wherein the surface has an iso pattern with a metal layer to dielectric structure pattern density of less than 20 percent, the metal layer has a width at the surface of less than 20 nm, and performing the CMP on the surface results in a height of the metal layer of between 20 and 23 nm.

19. The method of claim 15, wherein the metal layer is a first metal layer spaced apart on the dielectric structure from a second metal layer at the surface by a dimension of greater than 300 nm, wherein performing the CMP on the surface results in a dishing of the dielectric structure between the first metal layer and the second metal layer of 4 nm or less.

20. The method of claim 15, wherein the CMP slurry includes about 1.0 wt. % to about 10.0 wt. % of the compound.
